(19) United States
(12) Patent Application Publication
(10) Pub. No.: US 2016/0231629 A1
(43) Pub. Date: Aug. 11, 2016

(54) ARRAY SUBSTRATE AND MANUFACTURING METHOD THEREOF, AND LIQUID CRYSTAL DISPLAY PANEL

(71) Applicant: SHENZHEN CHINA STAR OPTOELECTRONICS TECHNOLOGY CO. , LTD., Shenzhen, Guangdong (CN)

(72) Inventor: Xiangyang XU, Shenzhen (CN)

(21) Appl. No.: 14/382,963

(22) PCT Filed: May 15, 2014
(86) PCT No.: PCT/CN2014/077594

§ 371 Date: Sep. 4, 2014

(30) Foreign Application Priority Data
Mar. 3, 2014 (CN) 201410075645.1

(51) Int. Cl. G02F 1/1362; G02F 1/1368; H01L 29/423; H01L 27/12; H01L 29/51; H01L 29/49; G02F 1/1333; G02F 1/1343

(52) U.S. Cl. CPC G02F 1/136227; G02F 1/133345; G02F 1/1368; G02F 1/134309; H01L 27/1218; H01L 29/513; H01L 29/4908; H01L 29/42364; H01L 27/1259; H01L 29/42356; G02F 2001/133302

(57) ABSTRACT

The present invention relates to an array substrate and a manufacturing method thereof, and also a liquid crystal display panel. The array substrate comprises a glass substrate; a patterned gate metal layer formed on the glass substrate; a gate insulating layer formed on the gate metal layer; a patterned organic insulating layer formed on the gate insulating layer, wherein the organic insulating layer being provided with an open pore in the area corresponding to a transistor gate in the gate metal layer; a patterned active layer formed on the organic insulating layer, wherein a part of the active layer being deposited at the periphery and interior of the open pore in the organic insulating layer; and a patterned source-drain metal layer formed on the active layer.

### FIELD OF THE INVENTION

The present disclosure relates to an image display technology, in particular to an array substrate and a manufacturing method thereof, and a liquid crystal display panel using the same.

### BACKGROUND OF THE INVENTION

A display device using a liquid crystal display panel as its core component is already widely applied in the daily life and work. The operation performance of the liquid crystal display panel has significant influence on the imaging effects of the display device, such as viewable angle, brightness, color and the like.

A liquid crystal display panel generally consists of an array substrate, a color filter substrate and a liquid crystal layer. In the case, the array substrate consists of a plurality of transistors arranged in the form of array and pixels each of which corresponds to a transistor. A transistor is a logic switching element for enabling a pixel to work. For the transistor, a scan signal from a scan driving circuit is received through a scan line, while a data signal from a data driving circuit is received through a data line, and under the action of the scan signal, the transistor transmits the data signal to its corresponding pixel. Liquid crystal molecules of the pixel correspondingly deflect under the action of the data signal, so that a certain quantity of light is transmitted. At the meanwhile, the light intensity thereof is father adjusted by a peripheral gray-scale adjusting circuit, and thus image display is achieved. It could thus be seen that, the liquid crystal display panel is a type of passive display component, and the power consumption thereof may be roughly classified into the following three forms, i.e., backlight power consumption, driving circuit board power consumption and panel power consumption. In this case, the backlight power consumption mainly depends on the brightness and luminous efficiency of LEDs; the driving circuit board power consumption mainly depends on signal frequency, driving current and wire loss; and the panel power consumption is mainly a type of logic power consumption, namely energy consumption required for driving logic switching elements on the array substrate. Among these, the design of the panel would directly affect the level of the panel power consumption.

With development of the display technology, the size of a liquid crystal display panel is continuously increased, and elements and wires in the panel is multiplied in term of quantity. Thus, how to reduce the panel power consumption becomes a problem against development of the liquid crystal display technology. Particularly, how to reduce the power loss of the panel due to coupled capacitive reactance between metal lines is a technical problem to be urgently solved.

### SUMMARY OF THE INVENTION

To solve the above-mentioned problems, the present disclosure provides a new array substrate with relatively low power consumption and a manufacturing method thereof, and also a corresponding liquid crystal display panel using the same.

The array substrate comprises:
a glass substrate;
a patterned gate metal layer formed on the glass substrate;
a gate insulating layer formed on the gate metal layer;
a patterned organic insulating layer formed on the gate insulating layer, wherein the organic insulating layer is provided with an open pore in the area thereof corresponding to a transistor gate laying in the gate metal layer;
a patterned active layer formed on the organic insulating layer, wherein a part of the active layer is deposited at the periphery and interior of the open pore in the organic insulating layer; and
a patterned source-drain metal layer formed on the active layer.

Preferably, in the above-mentioned array substrate, the open pore of the organic insulating layer is a through hole for exposing the area of the gate insulating layer which corresponds to the transistor gate laying in the gate metal layer.

According to an embodiment of the present disclosure, the thickness of the above-mentioned organic insulating layer may be 10,000 Å˜30,000 Å.

According to an embodiment of the present disclosure, the above-mentioned organic insulating layer may be made of polyacrylic acid.

According to an embodiment of the present disclosure, the above-mentioned array substrate may further include:
a patterned passivation protective layer formed on the source-drain metal layer; and
a patterned pixel electrode layer formed on the passivation protective layer.

In addition, the present disclosure further provides a liquid crystal display panel including the above-mentioned array substrate.

In addition, the present disclosure further provides a method for manufacturing the above-mentioned array substrate, comprising the steps of:
providing a glass substrate;
forming a patterned gate metal layer on the glass substrate;
forming a gate insulating layer on the gate metal layer;
forming a patterned organic insulating layer on the gate insulating layer, and providing an open pore at the area in the organic insulating layer which corresponds to a transistor gate laying in the gate metal layer;
forming a patterned active layer on the organic insulating layer, wherein a part of the active layer is deposited at the periphery and interior of the open pore in the organic insulating layer; and
forming a patterned source-drain metal layer on the active layer.

Preferably, the above-mentioned open pore of the organic insulating layer may be configured as a through hole for exposing the area in the gate insulating layer which corresponds to the transistor gate laying in the gate metal layer.

According to an embodiment of the present disclosure, the above-mentioned manufacturing method may further include the steps of:
forming a patterned passivation protective layer on the source-drain metal layer; and
forming a patterned pixel electrode layer on the passivation protective layer.

Preferably, in the above-mentioned manufacturing method, the thickness of the organic insulating layer may be set to be 10,000 Å˜30,000 Å.

Compared with the prior art, the present disclosure has the advantages that during manufacturing of the array substrate of the liquid crystal display panel, the organic insulating layer (a photoresist with high transmittance and low dielectric constant) is arranged on the gate metal layer to increase a distance between the gate metal layer and the source-drain metal layer, so as to reduce the coupling capacitive reactance at the intersections of metal lines and between the metal lines, thus reducing a load . related to the whole array substrate, decreacing the logic power consumption of the panel and prolonging its service life. Moreover, because the organic insulating layer is relatively thick and planar, electrostatic phenomenon may be effectively prevented and climbing disconnection of the metal lines is avoided, so that the production yield of the display panel is improved while the production cost is reduced. The technical solution proposed by the present disclosure is applicable to various types of liquid crystal display panels, such as PSVA.

### BRIEF DESCRIPTION OF THE DRAWINGS

The accompanying drawings are provided for further understanding of the present disclosure, and constitute a part of the description for explaining the present disclosure together with the embodiments without limiting the present disclosure. In the accompanying drawings:

FIG. 1 is a structural sectional view of an array substrate according to one embodiment of the present disclosure;

FIG. 2 is a sectional view of a gate metal layer deposited during manufacturing of the array substrate of FIG. 1 according to a manufacturing method of the present disclosure;

FIG. 3 is a sectional view of a gate insulating layer deposited during manufacturing of the array substrate of FIG. 1 according to the manufacturing method of the present disclosure;

FIG. 4 is a sectional view of an organic insulating layer deposited during manufacturing of the array substrate of FIG. 1 according to the manufacturing method of the present disclosure;

FIG. 5 is a sectional view of an active layer and a source-drain metal layer deposited during manufacturing of the array substrate of FIG. 1 according to the manufacturing method of the present disclosure; and

FIG. 6 is a sectional view of a passivation protective layer deposited during manufacturing of the array substrate of FIG. 1 according to the manufacturing method of the present disclosure.

### DETAILED DESCRIPTION OF THE EMBODIMENTS

In order to present the objectives, technical solutions and advantages of the present disclosure more apparently, the present disclosure will be further illustrated in detail below in combination with specific embodiments and accompanying drawings.

FIG. 1 is a schematic diagram of an array substrate manufactured according to a manufacturing method proposed by the present disclosure. The array substrate may be a PSVA type array substrate with low power consumption, which includes:
a glass substrate 110;
a patterned gate metal layer 120 formed on the glass substrate 110;
a gate insulating layer 130 formed on the gate metal layer 120;
a patterned organic insulating layer 140 formed on the gate insulating layer 130, wherein the organic insulating layer 140 is provided with an open pore 141 at the area corresponding to a transistor gate 121 laying in the gate metal layer 120, to expose the area of the gate insulating layer 130 that corresponds to the the transistor gate 121 laying in the gate metal layer 120;
a patterned active layer 150 formed on the organic insulating layer 140, wherein a part of the active layer 150 is deposited on the periphery and interior of the open pores 141 of the organic insulating layer 140;
a patterned source-drain metal layer 160 formed on the active layer 150;
a patterned passivation protective layer 170 formed on the source-drain metal layer 160;
a patterned pixel electrode layer 180 formed on the passivation protective layer 170.

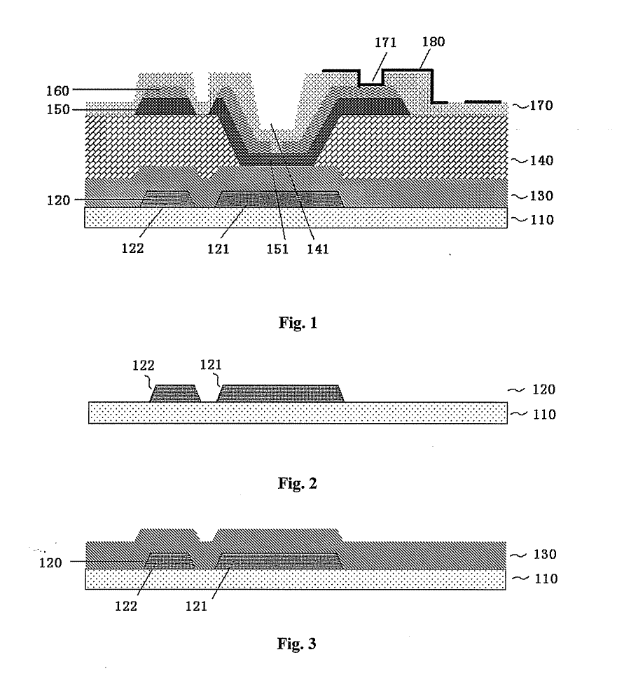

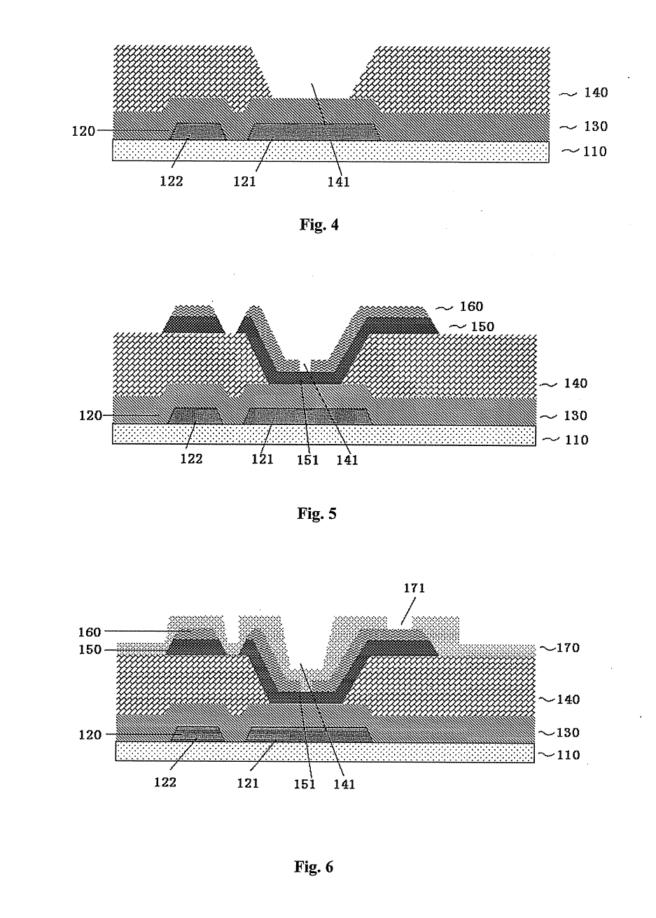

FIG. 1 to FIG. 6 are specific process flows for manufacturing the above-mentioned PSVA type array substrate, and the following steps are included.
1) A glass substrate 110 is provided.
2) A layer of metal, such as molybdenum, chromium, copper or other metal materials, is deposited on the glass substrate 110 by means of sputter coating (also referred to as sputtering). The thickness of this metal layer may be 2,000 Å˜5,000 Å. Then, the metal layer is patterned through lithography processes, such as exposure, developing, etching and stripping, by means of a mask so as to form a gate metal layer 120 including a plurality of transistor gates 121 and a plurality of gate metal lines 122 (see FIG. 2).
3) A layer of insulating material, such as silicon nitride, is deposited on the gate metal layer 120 by means of plasma-enhanced chemical vapor deposition (PECVD), which layer is used as a gate insulating layer 130 for protecting the gate metal layer 120 (see FIG. 3). The thickness of the gate insulating layer 130 may be 2,000 Å˜5,000 Å.
4) A layer of organic insulating material, such as polyacrylic acid, with high transmittance and low dielectric constant is coated on the gate insulating layer 130. The thickness of the coated layer is preferably 10,000 Å˜30,000 Å for increasing a distance between the gate metal layer 120 and a source-drain metal layer 160, so as to reduce the coupling capacitive reactance between metal lines, such as between the gate metal line and the drain metal line or between the gate metal line and the source metal line. Then, the coated layer is patterned through processes, such as exposure and developing, to form an organic insulating layer 140. An open pore 141 is formed in the area of the organic insulating layer 140 which corresponds to a transistor gate 121 of the gate metal layer 120. The open pore 141 is generally a through hole and used to expose the area of the gate insulating layer 130 which corresponds to the transistor gate 121 of the gate metal layer 120 (see FIG. 4).
5) By means of PECVD, hydrogenated amorphous silicon a-Si:H and metal materials used for preparing a drain metal line and a source metal line are deposited on the organic insulating layer 140 respectively, and the thickness of the coated layers may be, repecitvely, 1,000 Å˜6,000 Å. Then, the coated layers are patterned, by means of a gray-scale mask, through patterning processes, such as exposure, developing, primary S/D wet etching, primary a-Si dry etching and channel photoresist ashing, and then secondary channel S/D wet etching, channel N+ dry etching and stripping, so as to form an active layer 150 including a plurality of transistor channels and a source-drain metal layer 160 including a plurality of drain and source metal lines. In this case, the source-drain metal layer 160 is deposited on the active layer 150, while a part of the active layer 150 is deposited at the periphery of the open pores 141 in the organic insulating layer 140, and another part thererof is deposited at the interior of the open pores 141, namely directly on the gate insulating layer 130 (see FIG. 5). By this way, a distance between a transistor channel 151 of the active layer 150 and its corresponding gate 121 in the gate metal layer 120 is shorten, which ensures that a transistor therein can be driven to work in a normal manner.
6) A layer of insulating material, such as silicon nitride SiNx, is deposited on the source-drain metal layer 160 by means of PECVD, and it is used as a passivation protective layer 170 to protect the source-drain metal layer 160. The thickness of the passivation protective layer 170 may be 1,000 Å˜6,000 Å. Then, the passivation protective layer 170 is patterned, using a mask, through lithography processes of exposure, developing, etching, strippng and the like, so that a through pore 171 is formed in the passivation protective layer 170 to expose a portion of the drain metal line and/or the source metal line laying in the source-drain metal layer 160 (see FIG. 6).
7) A layer of transparent conductive material, such as ITO or 170, is deposited on the passivation protective layer 170 by sputtering, and the thickness thereof may be 100 Å˜1,000 Å. Then, the transparent conductive material layer is patterned through lithography processes of exposure, developing, etching, stripping and the like by means of a mask, so as to form a patterned pixel electrode layer 180. A part of the pixel electrode layer 180 is deposited at periphery of the open pore 171 laying in the passivation protective layer 170, and another part is deposited at interior of the open pore 171, namely directly on the drain metal line and/or source metal line in the source-drain metal layer 160 (see FIG. 1).

Through the above-mentioned method, the organic insulating layer (a photoresist with high transmittance and low dielectric constant) is arranged on the gate metal layer of the array substrate to increase the distance between the gate metal layer and the source-drain metal layer, so as to reduce the coupling capacitive reactance at the intersections of metal lines and between the metal lines, by means of which a load related to the whole array substrate can be smaller, the logic power consumption of the array substrate can be lowered and its service life is further prolonged. Moreover, since the organic insulating layer is relatively thick and planar, electrostatic phenomenon may be effectively prevented, and climbing disconnection of the metal lines is avoided, so that the production yield of the panel is improved while the cost thereof is reduced.

Of course, the array substrate and the manufacturing method thereof proposed by the present disclosure are not limited to the above-mentioned embodiments, and the present disclosure may also be applicable to other types of array substrates.

In addition, the present disclosure further proposes a liquid crystal display panel including the above-mentioned array substrate.

The foregoing descriptions are merely to provide preferred specific implementations of the present disclosure, rather than to limit the protection scope of the present disclosure. Any variations or alternatives readily conceivable by one skilled familiar with this art in term of the disclosed technical scope of the present disclosure shall fall within the protection scope of the present disclosure. Accordingly, the protection scope of the present disclosure should be subjected to the protection scope of the claims.

1. An array substrate, comprising:
a glass substrate;
a patterned gate metal layer formed on the glass substrate;
a gate insulating layer formed on the gate metal layer;
a patterned organic insulating layer formed on the gate insulating layer, wherein the organic insulating layer is provided with an open pore in the area thereof corresponding to a transistor gate in the gate metal layer;
a patterned active layer formed on the organic insulating layer, wherein a part of the active layer is deposited at the periphery and interior of the open pore in the organic insulating layer; and
a patterned source-drain metal layer formed on the active layer.

2. An array substrate of claim 1, wherein the open pore of the organic insulating layer is a through hole for exposing the area of the gate insulating layer which corresponds to the transistor gate in the gate metal layer.

3. An array substrate of claim 1, wherein the thickness of the organic insulating layer is 10,000 Å˜30,000 Å.

4. An array substrate of claim 2, wherein the thickness of the organic insulating layer is 10,000 Å˜30,000 Å.

5. An array substrate of claim 1, wherein the organic insulating layer is made of polyacrylic acid.

6. An array substrate of claim 2, wherein the organic insulating layer is made of polyacrylic acid.

7. An array substrate of claim 3, wherein the organic insulating layer is made of polyacrylic acid.

8. An array substrate of claim 1, wherein further includes:
a patterned passivation protective layer formed on the source-drain metal layer; and
a patterned pixel electrode layer formed on the passivation protective layer.

9. A liquid crystal display panel including an array substrate, wherein the array substrate comprises:
a glass substrate;
a patterned gate metal layer formed on the glass substrate;
a gate insulating layer formed on the gate metal layer;
a patterned organic insulating layer formed on the gate insulating layer, wherein the organic insulating layer is provided with an open pore in the area thereof corresponding to a transistor gate in the gate metal layer;
a patterned active layer formed on the organic insulating layer, wherein a part of the active layer is deposited at the periphery and interior of the open pore in the organic insulating layer; and
a patterned source-drain metal layer formed on the active layer.

10. A liquid crystal display panel of claim 9, wherein the open pore of the organic insulating layer is a through hole for exposing the area of the gate insulating layer which corresponds to the transistor gate in the gate metal layer.

11. A liquid crystal display panel of claim 9, wherein the thickness of the organic insulating layer is 10,000 Å˜30,000 Å.

12. A liquid crystal display panel of claim 9, wherein the organic insulating layer is made of polyacrylic acid.

13. A liquid crystal display panel of claim 9, wherein the array substrate further includes:
a patterned passivation protective layer formed on the source-drain metal layer; and
a patterned pixel electrode layer formed on the passivation protective layer.

14. A method for manufacturing an array substrate, comprising the steps of providing a glass substrate;
forming a patterned gate metal layer on the glass substrate;
forming a gate insulating layer on the gate metal layer;
forming a patterned organic insulating layer on the gate insulating layer, and providing an open pore at the area in the organic insulating layer which corresponds to a transistor gate in the gate metal layer;
forming a patterned active layer on the organic insulating layer, wherein a part of the active layer is deposited at the periphery and interior of the open pore in the organic insulating layer; and
forming a patterned source-drain metal layer on the active layer.

15. A method of claim 14, wherein the open pore of the organic insulating layer is configured as a through hole for exposing the area in the gate insulating layer which corresponds to the transistor gate in the gate metal layer.

16. A method of claim 14, wherein father includes the steps of:
forming a patterned passivation protective layer on the source-drain metal layer; and
forming a patterned pixel electrode layer on the passivation protective layer.

17. A method of claim 14, wherein the thickness of the organic insulating layer is set to be 10,000 Å˜30,000 Å.
